(19) United States
(12) Patent Application Publication
(10) Pub. No.: US 2010/0129752 A1
(43) Pub. Date: May 27, 2010

(54) PHOTOSENSITIVE RESIN COMPOSITION, PHOTOSENSITIVE ELEMENT EMPLOYING THE SAME, METHOD OF FORMING RESIST PATTERN, AND PROCESS FOR PRODUCING PRINTED WIRING BOARD

(75) Inventors: Yoshiki Ajioka, Ibaraki (JP); Tatsuya Ichikawa, Ibaraki (JP); Mitsuo Matsuda, Fukui (JP); Takahiro Inatsugi, Fukui (JP)

Correspondence Address: GRIFFIN & SZIPL, PC, SUITE PH-1, 2300 NINTH STREET, SOUTH, ARLINGTON, VA, 22204, US

(73) Assignee: HITACHI CHEMICAL COMPANY, LTD., Tokyo (JP)

(21) Appl. No.: 11/916,212

(22) PCT Filed: May 15, 2006
(86) PCT No.: PCT/JP2006/309648

§ 371 Date: Feb. 3, 2010

(30) Foreign Application Priority Data
May 30, 2005 (JP) 2005-157173

(51) Int. Cl. G03F 7/027; G03F 7/20; H05K 3/00

(52) U.S. Cl. 430/271.1; 430/285.1; 430/311; 430/315; 430/313

(57) ABSTRACT

The photosensitive resin composition of the present invention is a photosensitive resin composition comprising:
(A) a binder polymer;
(B) a photopolymerizable compound with at least one polymerizable ethylenic unsaturated group in the molecule; and
(C) a photopolymerization initiator,
   wherein component (A) contains a polymer that contains a compound represented by the following general formula (I) as a polymerization component:

CH₂═C(L¹)-COOL² (I)

(wherein L¹ represents a hydrogen atom or methyl group and L² represents a C₂₋₂₀ alkyl group group)
and component (B) contains a compound represented by the following general formula (II):

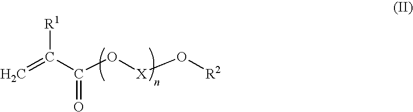

(wherein R¹ represents a hydrogen atom or methyl group, R² represents a C₃₋₂₀ alkyl group that has at least 2 tertiary or higher carbon atoms, X represents a C₂₋₆ alkylene group, and n is an integer from 1 to 20).

### TECHNICAL FIELD

The present invention relates to a photosensitive resin composition, a photosensitive element employing it, a method of forming a resist pattern, and a process for producing printed circuit board.

### BACKGROUND ART

A photosensitive element with a three-layer structure, i.e., a support, a photosensitive layer comprising a photosensitive resin composition, and a protective film, has heretofore been widely used as a resist material employed for, for example, etching or plating, in the field of printed circuit board production. When such a photosensitive element is used as a resist material, the protective film in the photosensitive element is first peeled off and press-bonding is then effected in such a manner that the photosensitive layer is in contact with the substrate (for example, a copper substrate). A phototool for pattern formation is then laid onto the support film in intimate contact therewith and exposure is carried out. The support film is then peeled off; the unexposed regions are removed (development) by spraying with a developing solution to thereby form a resist pattern; and this resist pattern is used as a resist in, for example, etching or plating (see, for example, patent document 1).

Recently, alkali developing types, which use, for example, sodium carbonate, as the developing solution, are the most prominent from the standpoint of enhancing safety, reducing the load on the environment, and reducing production costs. During development, an alkali developing type removes the unexposed regions by dissolving or dispersing the photosensitive resin composition into the developing solution.

However, in methods that use this alkali developing type developing solution, the photosensitive resin composition component dissolved or dispersed in the developing solution readily separates out as a solid sludge (referred to hereafter as development sludge) or an oil (referred to hereafter as scum). Defects, for example, short circuits, can be produced in the interconnects that are formed in subsequent steps when this development sludge and oil re-adhere to the substrate. In particular, the use of defoaming agents to inhibit foaming during development sets up conditions under which development sludge and scum are readily produced. In order to prevent the production of the interconnect short circuiting that is caused by development sludge and scum, the practice has therefore been to clean the developing equipment and change the circulation pump filter at high frequencies. However, the drive to reduce production costs requires that the frequency of such processes be reduced, and a photosensitive resin composition is therefore desired that resists the production of development sludge and scum even when an alkali development type developing solution is used.

For example, a photosensitive resin composition containing acrylate with polyethylene glycol chain has been proposed (see, for example, patent document 2) as a photosensitive resin composition designed to reduce scum. In addition, a photosensitive resin composition containing nonylphenoxypolyethyleneoxy acrylate, for example, has been proposed as a photosensitive resin composition designed to reduce development sludge (see, for example, patent documents 3 and 4).

[Patent document 1] Japanese Patent Application Laid-open No. H 4-195050
[Patent document 2] Japanese Patent Application Laid-open No. H 5-232699
[Patent document 3] Japanese Patent Application Laid-open No. 2000-314958
[Patent document 4] Japanese Patent Application Laid-open No. 2001-117224

### DISCLOSURE OF THE INVENTION

However, further improvement is required for the reasons provided below even in the case of the photosensitive resin compositions described in patent documents 2, 3 and 4.

Thus, according to investigations by the present inventors, use of the photosensitive resin composition according to patent document 2 in a photosensitive element can inhibit scum production, but it was also found that the development sludge cannot be adequately reduced in this case.

With regard to the use of photosensitive resin compositions according to patent documents 3 and 4 in a photosensitive element, investigations by the present inventors did show an inhibiting effect on development sludge to a certain degree. However, it was also found that printed circuit boards free of interconnect defects could not be obtained in good yields while at the same time achieving a satisfactory reduction in the frequency of cleaning the developing equipment and in the filter change frequency. The causes for this are thought to be an inadequate capacity to inhibit development sludge and an increase in the amount of development sludge produced when defoaming agents are used in order to prevent the problem of developing solution overflow and escape due to significant foaming during development.

The present invention was pursued in view of the circumstances described above and takes as an object the introduction of a photosensitive resin composition that can provide a satisfactory reduction in foaming during development while at the same time being able to provide a satisfactory reduction both in the amount of development sludge produced and in the amount of scum produced. Additional objects of the present invention are to provide a photosensitive element employing this photosensitive resin composition, a method of forming a resist pattern, and a process for producing a printed circuit board.

The photosensitive resin composition of the present invention is a photosensitive resin composition comprising:
(A) a binder polymer;
(B) a photopolymerizable compound with at least one polymerizable ethylenic unsaturated group in the molecule; and
(C) a photopolymerization initiator,
   characterized in that component (A) contains a polymer that contains a compound represented by the following general formula (I) as a polymerization component:

CH₂═C(L¹)-COOL² (I)

(wherein L¹ represents a hydrogen atom or methyl group and L² represents a C₂₋₂₀ alkyl group)
and component (B) contains a compound represented by the following general formula (II):

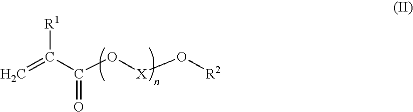

(wherein R¹ represents a hydrogen atom or methyl group, R² represents a C₃₋₂₀ alkyl group that has at least 2 tertiary or higher carbon atoms, X represents a C₂₋₆ alkylene group, and n is an integer from 1 to 20).

By means of a composition that contains, as essential components, polymer containing as a polymerization component a compound represented by the aforementioned general formula (I) as component (A), a compound represented by the aforementioned general formula (II) as component (B), and the aforementioned component (C), the photosensitive resin composition of the present invention, when used as a photosensitive element, can provide a satisfactorily low foaming during development and can provide a satisfactory reduction in the amounts of development sludge and scum produced during the development step. This in turn makes it possible to obtain printed circuit boards free of interconnect defects in good yields while at the same time achieving a good reduction in production costs through a reduction in the frequency at which the developing equipment is cleaned and a reduction in the frequency of filter change.

In addition, the photosensitive element of the present invention characteristically comprises a support and a photosensitive layer comprising the aforementioned photosensitive resin composition of the present invention formed on this support.

The photosensitive element of the present invention, because it is provided with a photosensitive layer comprising the aforementioned photosensitive resin composition of the present invention, can provide a satisfactorily low foaming during development and can provide a satisfactory reduction in the amounts of development sludge and scum produced during the development step. This in turn makes it possible to obtain printed circuit boards free of interconnect defects in good yields while at the same time achieving a good reduction in production costs through a reduction in the frequency at which the developing equipment is cleaned and a reduction in the frequency of filter change.

The method of the present invention for forming a resist pattern characteristically comprises: laminating the photosensitive layer in the aforementioned photosensitive element of the present invention on a circuit formation substrate; irradiating active light rays onto a prescribed region of the photosensitive layer to induce photocuring of the region exposed to light; and removing a region other than the region exposed to light.

This method of forming a resist pattern, because it uses the photosensitive element of the present invention, can provide low foaming and thorough inhibition of development sludge and scum production in the development step during resist pattern formation. This in turn makes it possible to obtain printed circuit boards free of interconnect defects in good yields while at the same time achieving a good reduction in production costs through a reduction in the frequency at which the developing equipment is cleaned and a reduction in the frequency of filter change.

The method of the present invention for producing a printed circuit board is characterized by etching or plating a circuit formation substrate on which a resist pattern has been formed by the method of forming a resist pattern of the present invention.

Due to its use of the method of the present invention for forming a resist pattern, the method of the present invention for producing a printed circuit board can provide low foaming and thorough inhibition of development sludge and scum production in the development step during resist pattern formation. This in turn makes it possible to obtain printed circuit boards free of interconnect defects in good yields while at the same time achieving a good reduction in production costs through a reduction in the frequency at which the developing equipment is cleaned and a reduction in the frequency of filter change.

### EFFECT OF THE INVENTION

The present invention provides a photosensitive resin composition that is capable of providing a satisfactorily low foaming during development and a good reduction in the amounts of development sludge and scum produced during development, as well as a photosensitive element, a method of resist pattern formation, and a process of a printed circuit board production employing it.

### BRIEF DESCRIPTION OF THE DRAWINGS

FIG. 1 is a schematic cross-sectional view showing a preferred embodiment of a photosensitive element of the present invention.

### DESCRIPTION OF SYMBOLS

1: photosensitive element, 10: support, 14: photosensitive layer

### BEST MODES FOR CARRYING OUT THE INVENTION

Hereinafter, preferred embodiments of the present invention will be described in detail. The term “(meth)acrylic acid” used throughout the present specification refers to “acrylic acid” and its corresponding “methacrylic acid”, the term “(meth)acrylate” refers to “acrylate” and its corresponding “methacrylate”, the term “(meth)acryloyl” refers to “acryloyl” and its corresponding “methacryloyl”, and the term “(meth)acryloxy” refers to “acryloxy” and its corresponding “methacryloxy”.

The photosensitive resin composition according to the present invention is a photosensitive resin composition comprising (A) a binder polymer, (B) a photopolymerizable compound with at least one polymerizable ethylenic unsaturated group in the molecule, and (C) a photopolymerization initiator, that contains, as component (A), a polymer that contains a compound represented by the following general formula (I) as a polymerization component

CH₂═C(L¹)-COOL² (I)

(in formula (I), L¹ represents a hydrogen atom or methyl group and L² represents C₂₋₂₀ alkyl)
and that contains, as component (B), a compound represented by the following general formula (II)

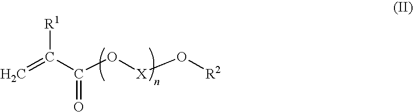

(in formula (II), R¹ represents a hydrogen atom or methyl group, R² represents C₃₋₂₀ alkyl that has at least 2 tertiary or higher carbon atoms, X represents C₂₋₆ alkylene, and n is an integer from 1 to 20).

<Component (A)>

Component (A) is a binder polymer and comprises polymer that contains a compound represented by the aforementioned general formula (I) as a polymerization component. The C₂₋₂₀ alkyl represented by L² in formula (I) can be exemplified by ethyl, n-propyl, isopropyl, n-butyl, sec-butyl, tert-butyl, isopentyl, neopentyl, and hexyl, heptyl, octyl, nonyl, decyl, undecyl, dodecyl, tridecyl, tetradecyl, pentadecyl, hexadecyl, heptadecyl, octadecyl, nonadecyl, eicosyl and their structural isomers.

Based on a consideration of obtaining additional reductions in the amount of scum and sludge during the development treatment, C₄₋₉ alkyl is preferred as the alkyl among the preceding and C₄₋₆ alkyl is more preferred.

The aforementioned compound represented by general formula (I) can be specifically exemplified by butyl (meth)acrylate, pentyl (meth)acrylate, hexyl (meth)acrylate, heptyl (meth)acrylate, octyl (meth)acrylate, 2-ethylhexyl (meth)acrylate, nonyl (meth)acrylate, decyl (meth)acrylate, undecyl (meth)acrylate, dodecyl (meth)acrylate, tridecyl (meth)acrylate, tetradecyl (meth)acrylate, pentadecyl (meth)acrylate, hexadecyl (meth)acrylate, heptadecyl (meth)acrylate, octadecyl (meth)acrylate, nonadecyl (meth)acrylate, and eicosyl (meth)acrylate. Any of these may be used alone or in combination of two or more.

The content of the aforementioned compound represented by general formula (I) in the polymer is preferably 3 to 70 mass % and more preferably is 10 to 40 mass % and particularly preferably is 15 to 30 mass % with respect to the total polymerization component. If this content is less than 3 mass %, obtaining a satisfactory reduction in the amount of development sludge and scum production will tend to be quite problematic, and if this content is greater than 70 mass %, it will tend to have an influence on film formation.

Compounds other than the aforementioned compound represented by general formula (I) can be used as a structural component of the polymer under consideration. These compounds can be exemplified by styrene, polymerizable styrene derivatives substituted at the α-position or on the aromatic ring, such as vinyltoluene and α-methylstyrene, acrylamides such as diacetone acrylamide; acrylonitrile; vinyl alcohol esters such as vinyl n-butyl ether, methyl (meth)acrylate; ethyl (meth)acrylate; propyl (meth)acrylate; (meth)acrylic acid alkyl esters; tetrahydrofurfuryl (meth)acrylate; dimethylaminoethyl (meth)acrylate; diethylaminoethyl (meth)acrylate; glycidyl (meth)acrylate; 2,2,2-trifluoroethyl (meth)acrylate; 2,2,3,3-tetrafluoropropyl (meth)acrylate; (meth)acrylic acid; α-bromo(meth)acrylic acid; α-chloro(meth)acrylic acid; β-furyl(meth)acrylic acid; β-styryl(meth)acrylic acid; maleic acid; maleic anhydride; maleic acid monoesters such as monomethyl maleate, monoethyl maleate, and monoisopropyl maleate; fumaric acid; cinnamic acid; α-cyanocinnamic acid; itaconic acid; crotonic acid; propiolic acid; and the like.

The aforementioned (meth)acrylic acid alkyl esters can be exemplified by compounds represented by the following general formula (III):

CH₂═C(L³)-COOL⁴ (III)

(in formula (III), L³ represents hydrogen atom or methyl group and L⁴ represents C₁₋₂₀ alkyl possibly having hydroxyl group, epoxy group, or halogen as a substituent). The compounds represented by general formula (III) can be used alone or in combination with two or more.

The aforementioned polymer preferably contains the carboxyl group from the perspective of obtaining a better alkali developing property. Such a polymer can be produced, for example, by inducing the radical polymerization of the aforementioned compound represented by general formula (I) with polymerizable monomer having a carboxyl group and optionally other polymerizable monomer. Methacrylic acid is preferred for polymerizable monomer having the carboxyl group.

From the standpoint of setting up a balance between the alkali developing properties and the alkali resistance, the carboxyl group content in the aforementioned polymer (proportion of carboxyl group-bearing polymerizable monomer with respect to the total polymerizable monomer used) is preferably 12 to 50 mass %, more preferably 12 to 40 mass %, particularly preferably 15 to 30 mass %, and very preferably 15 to 25 mass %. The alkali developing properties will tend to be inferior if this carboxyl group content is less than 12 mass %, while the alkali resistance will tend to be inferior if it is grater than 50 mass %.

The polymerizable monomer for this polymer preferably also includes styrene or a styrene derivative in order to bring about an additional increase in the flexibility.

In order to obtain both a good adherence and good stripping characteristics when styrene or a styrene derivative is used as a copolymerization component as mentioned above, the styrene or styrene derivative content, expressed with reference to the total amount of the copolymerization component, is preferably 0.1 to 30 mass %, more preferably is 1 to 28 mass %, and particularly preferably is 1.5 to 27 mass %. The adhesive property will tend to be inferior if this content is less than 0.1 mass %. There is a tendency for the stripped fragments to be large and for the stripping time to lengthen if it is greater than 30 mass %.

From the standpoint of striking a balance between mechanical strength and alkali developing properties, the weight-average molecular weight of the polymer under consideration is preferably 20,000 to 300,000, more preferably 40,000 to 150,000, and particularly preferably 50,000 to 100,000. If the weight-average molecular weight is less than 20,000 the resistance to the developing solution will tend to decline, while the development time will tend to lengthen if the weight-average molecular weight is greater than 300,000. As used in the present invention, the weight-average molecular weight refers to the value measured by gel permeation chromatography and calculated by means of a calibration curve prepared using polystyrene standards.

The polymers described above can be used alone or in combinations of two or more. As examples of polymers when two or more are used in combination, there may be mentioned two or more polymers composed of different copolymerizable components, two or more polymers with different weight-average molecular weights, two or more polymers with different dispersities, and so forth.

A combination of the above-described polymer with other binder polymer may also be used as component (A). This binder polymer can be exemplified by acrylic resins, styrenic resins, epoxy resins, amide resins, amidoepoxy resins, alkyd resins, phenolic resins, and the like. Acrylic resins are preferred from the standpoint of alkali developing properties.

<Component (B)>

Component (B) is a photopolymerizable compound with at least one polymerizable ethylenic unsaturated group in the molecule and includes the compound represented by the aforementioned general formula (II) as an essential component. The C₂₋₆ alkylene represented by X in formula (II) is exemplified by ethylene, propylene, isopropylene, butylene, isobutylene, pentylene, neopentylene, hexylene, and the like. Ethylene is preferred thereamong for X from the perspective of enabling increased sludge dispersibility.

The above-cited isopropylene group is the group represented by —CH(CH₃)CH₂—, and the position in the isopropylene group that is bonded to the oxygen atom in the —(O—X)— in formula (II) may be the methylene group or the methine group or a mixture thereof.

When n in the aforementioned formula (II) is two or more, the two or more X's may then be identical to one another or may differ from one another. When X represents two or more types of alkylene groups, the structural units in —(O—X)— may have a random or block configuration.

n in the aforementioned formula (II) is an integer from 1 to 20 and is preferably 3 to 15, more preferably 4 to 12, and particularly preferably 5 to 9 from the perspective of bringing about an even greater reduction in the development sludge and scum.

R² in the aforementioned formula (II) is C₅₋₂₀ alkyl with at least two tertiary or higher carbon atoms, and is preferably C₈₋₂₀, more preferably C₁₀₋₂₀ and particularly preferably C₁₃₋₂₀ from the standpoint of bringing about an even greater reduction in the scum and development sludge. C₅₋₂₀ alkyl with at least two tertiary or higher carbon atoms can be exemplified by the structural isomers of pentyl, hexyl, heptyl, octyl, nonyl, decyl, undecyl, dodecyl, tridecyl, tetradecyl, pentadecyl, hexadecyl, heptadecyl, octadecyl, nonadecyl, and eicosyl. Among these, R² is preferably the trimethyldecyl group which is a structural isomer of the tridecyl group, from the standpoint of bringing out increased sludge dispersibility.

R² in the above-cited formula (II) may also have substituents within a range that does not impair the effects of the present invention. These substituents can be exemplified by halogen atoms, C₁₋₂₀ alkyl, C₃₋₁₀ cycloalkyl, C₆₋₁₈ aryl, phenacyl, amino group, C₁₋₁₀ alkylamino, C₂₋₂₀ dialkylamino, nitro, cyano, carbonyl, mercapto group, C₁₋₁₀ alkylmercapto, allyl, hydroxyl, C₁₋₂₀ hydroxyalkyl, carboxyl, carboxyalkyl in which the alkyl is C₁₋₁₀, acyl in which the alkyl is C₁₋₁₀, C₁₋₂₀ alkoxy, C₁₋₂₀ alkoxycarbonyl, C₂₋₁₀ alkylcarbonyl, C₂₋₁₀ alkenyl, C₂₋₁₀ N-alkylcarbamoyl, groups containing a heterocycle, and aryl groups substituted by the preceding substituents. These substituents may form a condensed ring, and the hydrogen atom in these substituents may be further substituted by halogen atom or the preceding substituents. When R² has two or more substituents, the two or more substituents may be the same as one another or may differ from one another.

Component (B) may also use photopolymerizable compounds that have at least one polymerizable ethylenic unsaturated group in the molecule other than the aforementioned compound represented by formula (II).

Examples for component (B) other than the aforementioned compound represented by formula (II) are compounds obtained by reacting an α,β-unsaturated carboxylic acid with a polyhydric alcohol; bisphenol A-type (meth)acrylate compounds such as 2,2-bis(4-((meth)acryloxypolyethoxy)phenyl)propane, 2,2-bis(4-((meth)acryloxypolypropoxy)phenyl)propane, and 2,2-bis(4-((meth)acryloxypolyethoxypolypropoxy)phenyl)propane; compounds obtained by the reaction of an α,β-unsaturated carboxylic acid with a glycidyl-functional compound; urethane monomers such as (meth)acrylate compounds with urethane bond; γ-chloro-β-hydroxypropyl-β′-(meth)acryloyloxyethyl-o-phthalate; β-hydroxyethyl-β′-(meth)acryloyloxyethyl-o-phthalate; β-hydroxypropyl-β′-(meth)acryloyloxyethyl-o-phthalate; the alkyl esters of (meth)acrylic acid, and so forth. Bisphenol A-type (meth)acrylate compounds and (meth)acrylate compounds with urethane bond are preferred from the standpoints of adhesive property and resolution. These can be used alone or in combination of two or more.

The aforementioned compound obtained by the reaction of an α,β-unsaturated carboxylic acid with a polyhydric alcohol can be exemplified by polyethylene glycol di(meth)acrylate containing from 2 to 14 ethylene groups, polypropylene glycol di(meth)acrylate containing from 2 to 14 propylene groups, polyethylenepolypropylene glycol di(meth)acrylate containing from 2 to 14 ethylene groups and from 2 to propylene groups, trimethylolpropane di(meth)acrylate, trimethylolpropane tri(meth)acrylate, trimethylolpropane ethoxytri(meth)acrylate, trimethylolpropane diethoxytri(meth)acrylate, trimethylolpropane triethoxytri(meth)acrylate, trimethylolpropane tetraethoxytri(meth)acrylate, trimethylolpropane pentaethoxytri(meth)acrylate, tetramethylolmethane tri(meth)acrylate, tetramethylolmethane tetra(meth)acrylate, polypropylene glycol di(meth)acrylate containing from 2 to 14 propylene groups, dipentaerythritol penta(meth)acrylate, dipentaerythritol hexa(meth)acrylate, and so forth.

The aforementioned 2,2-bis(4-((meth)acryloxypolyethoxy)phenyl)propane can be exemplified by 2,2-bis(4-((meth)acryloxydiethoxy)phenyl)propane, 2,2-bis(4-((meth)acryloxytriethoxy)phenyl)propane, 2,2-bis(4-((meth)acryloxytetraethoxy)phenyl)propane, 2,2-bis(4-((meth)acryloxypentaethoxy)phenyl)propane, 2,2-bis(4-((meth)acryloxyhexaethoxy)phenyl)propane, 2,2-bis(4-((meth)acryloxyheptaethoxy)phenyl)propane, 2,2-bis(4-((meth)acryloxyoctaethoxy)phenyl)propane, 2,2-bis(4-((meth)acryloxynonaethoxy)phenyl)propane, 2,2-bis(4-((meth)acryloxydecaethoxy)phenyl)propane, 2,2-bis(4-((meth)acryloxyundecaethoxy)phenyl)propane, 2,2-bis(4-((meth)acryloxydodecaethoxy)phenyl)propane, 2,2-bis(4-((meth)acryloxytridecaethoxy)phenyl)propane, 2,2-bis(4-((meth)acryloxytetradecaethoxy)phenyl)propane, 2,2-bis(4-((meth)acryloxypentadecaethoxy)phenyl)propane, 2,2-bis(4-((meth)acryloxyhexadecaethoxy)phenyl)propane, and so forth. 2,2-bis(4-(methacryloxypentaethoxy)phenyl)propane can be commercially available as “BPE-500” (product name, Shin-nakamura Chemical Co., Ltd.), and 2,2-bis(4-(methacryloxypentadecaethoxy)phenyl)propane can be commercially available as “BPE-1300” (product name, Shin-nakamura Chemical Co., Ltd.). These can be used alone or in combination of two or more.

The aforementioned 2,2-bis(4-((meth)acryloxypolypropoxy)phenyl)propane can be exemplified by 2,2-bis(4-((meth)acryloxydipropoxy)phenyl)propane, 2,2-bis(4-((meth)acryloxytripropoxy)phenyl)propane, 2,2-bis(4-((meth)acryloxytetrapropoxy)phenyl)propane, 2,2-bis(4-((meth)acryloxypentapropoxy)phenyl)propane, 2,2-bis(4-((meth)acryloxyhexapropoxy)phenyl)propane, 2,2-bis(4-((meth)acryloxyheptapropoxy)phenyl)propane, 2,2-bis(4-((meth)acryloxyoctapropoxy)phenyl)propane, 2,2-bis(4-((meth)acryloxynonapropoxy)phenyl)propane, 2,2-bis(4-((meth)acryloxydecapropoxy)phenyl)propane, 2,2-bis(4-((meth)acryloxyundecapropoxy)phenyl)propane, 2,2-bis(4-((meth)acryloxydodecapropoxy)phenyl)propane, 2,2-bis(4-((meth)acryloxytridecapropoxy)phenyl)propane, 2,2-bis(4-((meth)acryloxytetradecapropoxy)phenyl)propane, 2,2-bis(4-((meth)acryloxypentadecapropoxy)phenyl)propane, 2,2-bis(4-((meth)acryloxyhexadecapropoxy)phenyl)propane, and so forth. These can be used alone or in combination of two or more.

The aforementioned 2,2-bis(4-((meth)acryloxypolyethoxypolypropoxy)phenyl)propane can be exemplified by 2,2-bis(4-((meth)acryloxydiethoxyoctapropoxy)phenyl)propane, 2,2-bis(4-((meth)acryloxytetraethoxytetrapropoxy)phenyl)propane, 2,2-bis(4-((meth)acryloxyhexaethoxyhexapropoxy)phenyl)propane, and so forth. These can be used alone or in combination of two or more.

The aforementioned urethane monomer can be exemplified by the adducts of (meth)acrylic monomer having OH in the β-position with a diisocyanate compound such as isophorone diisocyanate, 2,6-toluene diisocyanate, 2,4-toluene diisocyanate, 1,6-hexamethylene diisocyanate, and by tris((meth)acryloxytetraethylene glycol isocyanate)hexamethylene isocyanurate, EO-modified urethane di(meth)acrylate, EO, PO-modified urethane di(meth)acrylate, and so forth. Here, “EO” represents ethylene oxide and an EO-modified compound contains ethyleneoxy groups in a block structure. In addition, “PO” represents propylene oxide and a PO-modified compound contains propyleneoxy groups in a block structure. “UA-11” (product name, Shin-nakamura Chemical Co., Ltd.) is an example of a commercially available EO-modified urethane di(meth)acrylate. “UA-13” (product name, Shin-nakamura Chemical Co., Ltd.) is an example of a commercially available EO, PO-modified urethane di(meth)acrylate.

The photopolymerization initiator as component (C) can be exemplified by aromatic ketones such as benzophenone, N,N′-tetramethyl-4,4′-diaminobenzophenone (Michler's ketone), N,N′-tetraethyl-4,4′-diaminobenzophenone, 4-methoxy-4′-dimethylaminobenzophenone, 2-benzyl-2-dimethylamino-1-(4-morpholinophenyl)-butan-1 and 2-methyl-1-[4-(methylthio)phenyl]-2-morpholinopropan-1-one; quinones such as 2-ethylanthraquinone, phenanthrene quinone, 2-tert-butylanthraquinone, octamethylanthraquinone, 1,2-benzanthraquinone, 2,3-benzanthraquinone, 2-phenylanthraquinone, 2,3-diphenylanthraquinone, 1-chloroanthraquinone, 2-methylanthraquinone, 1,4-naphthoquinone, 9,10-phenanthraquinone, 2-methyl-1,4-naphthoquinone and 2,3-dimethylanthraquinone; benzoin ether compounds such as benzoin methyl ether, benzoin ethyl ether and benzoin phenyl ether; benzoin compounds such as benzoin, methylbenzoin and ethylbenzoin; benzil derivatives such as benzil dimethyl ketone; 2,4,5-triarylimidazole dimers such as 2-(o-chlorophenyl)-4,5-diphenylimidazole dimer, 2-(o-chlorophenyl)-4,5-di(methoxyphenyl)imidazole dimer, 2-(o-fluorophenyl)-4,5-diphenylimidazole dimer, 2-(o-methoxyphenyl)-4,5-diphenylimidazole dimer and 2-(p-methoxyphenyl)-4,5-diphenylimidazole dimer; acridine derivatives such as 9-phenylacridine and 1,7-bis(9,9′-acridinyl)heptane; as well as N-phenylglycine, N-phenylglycine derivatives, coumarin-type compounds, and so forth. Moreover, the substituents on the aryl groups in the two 2,4,5-triarylimidazoles may be the same to yield a symmetrical compound, or they may be different to yield an asymmetrical compound. Like a combination of diethyl thioxanthone and diethylaminobenzoic acid, a thioxanthone compound and a tertiary amine compound may be combined. 2,4,5-triarylimidazole dimers are more preferred from the standpoint of the adhesive property and photosensitivity. Any one of these may be used alone, or two or more thereof may be used in combination.

The content of the aforementioned binder polymer (A) is preferably 30 to 80 parts by mass and more preferably 50 to 70 parts with respect to 100 parts by mass as the total of components (A) and (B). If this content is less than 30 parts by mass the photocured composition will tend to be brittle, and the coatability poor for use as a photosensitive element, while if the content is greater than 80 parts by mass the photosensitivity will tend to be inadequate.

The content of the aforementioned photopolymerizable compound (B) is preferably 20 to 70 parts by mass and more preferably 30 to 50 parts by mass with respect to 100 parts by mass as the total of components (A) and (B). If this content is less than 20 parts by mass the photosensitivity will tend to be inadequate, while if it is greater than 70 parts by mass the photocured material will tend to become brittle.

The content of the aforementioned compound represented by general formula (II) is preferably 1 to 95 mass %, more preferably 5 to 60 mass %, and particularly preferably 10 to 40 mass % with respect to the total amount of component (B). If the content of the compound represented by general formula (II) is less than 1 mass % with respect to the total amount of component (B) achieving a satisfactory reduction in the amount of development sludge and scum produced will tend to become quite problematic, while if it is greater than 95 mass % the adhesive property will tend to decrease.

The content of the aforementioned photopolymerization initiator (C) is preferably 0.01 to 20 parts by mass, more preferably 0.1 to 10 parts by mass, and particularly preferably 0.2 to 5 parts by mass, with respect to 100 parts by mass as the total of components (A) and (B). If this content is less than 0.01 mass part the photosensitivity will tend to become inadequate, and if it is greater than 20 parts by mass the absorption by the composition on the surface of the photosensitive resin composition layer will be increased during exposure, tending to result in insufficient photocuring in the interior.

The photosensitive resin composition of the present invention may, if necessary, also contain dyes such as malachite green; photodevelopers such as tribromophenylsulfone and leuco crystal violet; thermal coloring inhibitors; plasticizers such as p-toluenesulfonamide; pigments; fillers, defoaming agents; flame retardants; stabilizers; tackifiers; leveling agents; release accelerators; antioxidants; fragrances; imaging agents; thermal crosslinking agents; and so forth. Any of these additives can be used alone, or two or more thereof can be used in combination. For each of these additives, the content is preferably about 0.01 to 20 parts by mass per 100 parts by mass with respect to 100 parts by mass as the total amount of components (A) and (B).

As necessary, the photosensitive resin composition of the present invention can be dissolved in a solvent such as methanol, ethanol, acetone, methyl ethyl ketone, methyl cellosolve, ethyl cellosolve, toluene, N,N-dimethylformamide, propylene glycol monomethyl ether, or in a mixture of such solvents, and coated as a solid content of about 30-60 mass % solution.

While not particularly limited by the following, the photosensitive resin composition of the present invention is preferably coated as a liquid resist on a metal surface, e.g., on the surface of copper, a copper alloy, nickel, chromium, iron, an iron alloy such as stainless steel, and preferably copper, a copper alloy, or an iron alloy, thereafter dried and then used, optionally after coating with a protective film, or is preferably used in the form of a photosensitive element.

While the thickness of the photosensitive layer varies as a function of the application, the post-drying thickness is preferably 1 to 200 μm and more preferably is 1 to 100 μm. If this thickness is less than 1 μm the coating process at an industrial level will tend to be quite problematic, while if the thickness is greater than 200 μm the effect of the present invention will be minimal and the sensitivity will tend to become inadequate and the photocurability at the bottom of the resist will tend to deteriorate.

The photosensitive element of the present invention is described herebelow.

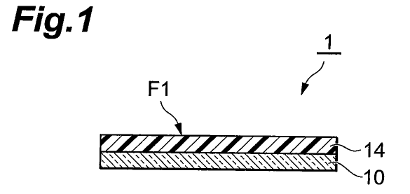

FIG. 1 is a schematic cross-sectional view showing a preferred embodiment of a photosensitive element of the present invention. The photosensitive element 1 shown in FIG. 1 has a structure in which a photosensitive layer 14 is laminated on a support 10. The photosensitive layer 14 is consisting of a layer of the photosensitive resin composition of the present invention as described hereinabove.

The support 10 may be a polymer film having heat resistance and solvent resistance, such as polyethylene terephthalate, polypropylene, polyethylene and polyester for example. The use of polyethylene terephthalate film is preferred from the perspective of obtaining transparency. The thickness of the support is preferably 1 to 100 μM and more preferably is 1 to 30 μm. If the thickness is less than 1 μm it will tend to occur problems such as a reduction in the mechanical strength and tearing of the polymer film during the coating operation, while if it is greater then 100 μm the resolution will tend to decline and the costs will tend to become elevated.

The photosensitive layer 14 can be formed by coating the hereinabove-described photosensitive resin composition of the present invention as a liquid resist on the support 10.

The solution of solid content of 30 to 60 mass % prepared by dissolving the photosensitive resin composition in a prescribed solvent can optionally be used as the coating solution when the photosensitive resin composition is coated on the support 10. This solvent can be exemplified by organic solvents such as methanol, ethanol, acetone, methyl ethyl ketone, methyl cellosolve, ethyl cellosolve, toluene, N,N-dimethylformamide and propylene glycol monomethyl ether, and a mixture of such solvents.

The coating method can be exemplified by known methods, such as a roll coater, comma coater, gravure coater, air knife coater, die coater, bar coater and spray coater. The solvent can be removed, for example, by heating, in which case the heating temperature is preferably approximately 70 to 150° C. and the heating time is preferably approximately 5 to 30 minutes.

The amount of residual organic solvent in the photosensitive layer 14 formed in this manner, from the standpoint of avoiding the diffusion of organic solvent in subsequent processes, is preferably no more than 2 mass %.

While the thickness of the photosensitive layer 14 will differ depending on the purpose, its thickness after solvent removal is preferably about 1 to 100 μm. If the thickness is less than 1 μm it will tend to be difficult to accomplish industrial coating, while if it is greater than 100 μm the effect of the invention will be minimal and the sensitivity will tend to become inadequate and the photocurability at the bottom of the resist will tend to deteriorate.

The side F1 of the photosensitive element 1 that is opposite the support side of the photosensitive layer 14 may optionally be coated with a protective film (not shown).

This protective film can be exemplified by polymer films such as polyethylene and polypropylene. The protective film is preferably a low-fisheye film, and the adhesive strength between the protective film and the photosensitive layer 14 is preferably less than the adhesive strength between the photosensitive layer 14 and the support 10 in order to facilitate stripping of the protective film from the photosensitive layer 14.

The photosensitive element 1, for example, can be stored as such in a flat configuration or can be stored in a roll configuration yielded by laminating a protective film on one side (on the exposed, unprotected side) of the photosensitive layer and winding up on, for example, a cylindrical core. This core can be a core as heretofore used and is not otherwise particularly limited and can be exemplified by a plastic such as polyethylene resin, polypropylene resin, polystyrene resin, polyvinyl chloride resin and ABS resin (acrylonitrile-butadiene-styrene copolymer). Wind up for storage is preferably carried out in such a manner that the support is on the outermost side. In addition, an end separator is preferably disposed at the end surfaces of the roll-wound photosensitive element (photosensitive element roll) based on a consideration of end surface protection, and a moisture-resistant end separator is preferably employed from the standpoint of resistance to edge fusion. When the photosensitive element 1 is packaged, it is preferably packaged wrapped in a black sheet that has a low moisture permeability.

The method of the present invention for forming a resist pattern is now described herebelow.

The method of the present invention for forming a resist pattern is a method in which the above-described photosensitive element 1 is laminated on a circuit formation substrate in such a manner that the photosensitive layer 14 is in intimate contact therewith; imagewise irradiation is carried out with active light rays to induce photocuring of the exposed regions; and the unexposed regions (photocured regions) are removed by development. Here, “circuit formation substrate” denotes a substrate that is provided with an insulating layer and with a conductor layer formed on the insulating layer.

The method for laminating the photosensitive layer 14 on the circuit formation substrate can be exemplified by removing the protective film, in those instances where the photosensitive element is provided with a protective film, and thereafter press-bonding the photosensitive layer 14 to the circuit formation substrate using a pressure of about 0.1 to 1 MPa (about 1 to 10 kgf/cm²) while heating to about 70 to 130° C. This laminating step may be carried out in a vacuum. The surface of the substrate to which the photosensitive layer 14 is laminated is generally a metal surface, but is not particularly limited. In addition, the circuit formation substrate is preferably subjected in advance to a pre-heat treatment from the standpoint of bringing about an additional improvement in the laminating property.

The photosensitive layer 14 laminated on the substrate proceeding as described above is imagewise irradiated with active light rays passing through a negative or positive mask pattern in order to form exposed regions. At this point, the active light rays can be irradiated through the support 10 in those instances where the support 10 present on the photosensitive layer 14 is transparent to the active light rays; in those instances where the support 10 shuts out the active light rays, the photosensitive layer 14 is exposed to active light rays after the support 10 has been removed.

The light source used for the active light rays can be the heretofore known light sources, for example, the heretofore known light sources that effectively emit ultraviolet rays such as carbon arc lamps, mercury vapor arc lamps, high-pressure mercury lamps, xenon lamps and so forth, or visible light rays. Light exposure by laser direct imaging, inter alia, can also be used.

After formation of the exposed regions, a resist pattern is formed by removing the photosensitive layer outside the exposed regions (the unexposed regions) by development. The method of removing these unexposed regions can be exemplified by removal of the support 10, for example, with an autopeeler, in those instances where a support 10 is present on the photosensitive layer 14, and then carrying out development to remove the unexposed regions, for example, by dry development or wet development using a developing solution such as an alkaline aqueous solution, a water-based developing solution, and organic solvent.

The base in the alkaline aqueous solution can be exemplified by the alkali hydroxides such as a hydroxide of lithium, sodium or potassium; alkali carbonates such as a carbonates or a bicarbonate of lithium, sodium, potassium or ammonium; an alkali metal phosphate such as potassium phosphate or sodium phosphate; and an alkali metal pyrophosphate such as sodium pyrophosphate or potassium pyrophosphate. The alkaline aqueous solutions used for wet development can be exemplified by a 0.1 to 5 mass % dilute sodium carbonate solution, 0.1 to 5 mass % dilute potassium carbonate solutions, a 0.1 to 5 mass % dilute sodium hydroxide solution, and a 0.1 to 5 mass % dilute sodium tetraborate solution. The pH of the alkaline aqueous solution is preferably in the range from 9 to 11, and its temperature is adjusted in conformity with the developing property of the photosensitive layer. The alkaline aqueous solution may also contain surfactants, defoaming agents, organic solvent and the like.

The aforementioned water-based developing solution can be exemplified by developing solutions that contain at least one type of organic solvent and water or an alkaline aqueous solution. The basic compound present in this alkaline aqueous solution can be exemplified by the alkali salts cited above and also by borax, sodium metasilicate, tetramethylammonium hydroxide, ethanolamine, ethylenediamine, diethylenetriamine, 2-amino-2-hydroxymethyl-1,3-propanediol, 1,3-diaminopropan-2-ol, morpholine, and so forth. The organic solvent can be exemplified by 3 acetone alcohol, acetone, ethyl acetate, alkoxyethanol containing C₁₋₄ alkoxy, ethyl alcohol, isopropyl alcohol, butyl alcohol, diethylene glycol monomethyl ether, diethylene glycol monoethyl ether and diethylene glycol monobutyl ether. Any of these can be used alone or in combination of two or more. The organic solvent concentration is preferably 2 to 90 mass %.

The pH of the water-based developing solution is preferably relatively lower within the range in which resist development can be satisfactorily effected, and specifically is preferably pH 8 to 12 and more preferably is pH 9 to 10. The temperature of the water-based developing solution is adjusted in conformity with the developability of the photosensitive layer. In addition, surfactant, defoaming agents, organic solvent and the like may be present in the alkaline aqueous solution.

The organic solvent-based developing solution, which uses organic solvent by itself, can be exemplified by 1,1,1-trichloroethane, N-methylpyrrolidone, N,N-dimethylformamide, cyclohexanone, methyl isobutyl ketone, γ-butyrolactone and the like. Water is preferably added in a range of 1 to 20 mass % for anti-flammability.

Two or more of the preceding developing solutions may optionally be used in combination.

The development method can be exemplified by dipping, spraying, brushing, slapping and the like. The use of a high-pressure spray procedure is preferred among there for improved resolution.

As a post-development treatment, additional curing of the resist pattern may optionally be carried out by means of heating at about 60 to 250° C. or photoexposure with about 0.2 to 10 J/cm².

The process for producing printed circuit boards of the present invention is described in the following.

The process for producing printed circuit boards of the present invention is a method characterized by etching or plating a circuit formation substrate on which a resist pattern has been formed by the above-described method of the present invention for forming a resist pattern.

The etching or plating of the circuit formation substrate is carried out, for example, on the conductor layer of the circuit formation substrate using as a mask the resist pattern that has been formed. The etching solution can be exemplified by a cupper(II) chloride solution, iron(II) chloride solution, alkali etching solution, hydrogen peroxide-type etching solution and the like. The use of a iron(II) chloride solution is preferred thereamong for its good etch factor. In those instances where plating is carried out, the type of plating can be exemplified by copper plating such as copper sulfate plating and copper pyrophosphate plating; solder plating suck as high-throw solder plating; nickel plating such as Watt bath (nickel sulfate-nickel chloride) plating and nickel sulfaminate plating; and gold plating suck as hard gold plating and soft gold plating.

After the completion of etching or plating, the resist pattern, for example, can be stripped off using an aqueous solution more strongly alkaline than the alkaline aqueous solution used for development. This strongly alkaline aqueous solution can be exemplified by a 1 to 10 mass % aqueous sodium hydroxide solution, a 1 to 10 mass % aqueous potassium hydroxide solution and the like. The stripping procedure can be exemplified by immersion, spraying, and so forth. A single one of these stripping procedures can be used, or combinations of these stripping procedures can be used.

A printed circuit board is obtained proceeding as above, but the process for producing printed circuit board of the present invention, through its use of the photosensitive element 1 of the present invention, which provides a satisfactorily low foaming during development and a thorough reduction in the production of scum and development sludge, can produce printed circuit boards free of interconnect defects in good yields while at the same time achieving a good reduction in production costs through a reduction in the frequency at which the developing equipment is cleaned and in the filter change frequency. The printed circuit board according to the present invention may be a multilayer printed circuit board and can have small-diameter thru-holes.

### EXAMPLES

The present invention will be specifically described by the following examples, but the present invention is not limited to these examples.

<Binder Polymer Synthesis>

(Binder Polymer 1)

600 parts by mass of a mixed solution of methyl cellosolve and toluene (methyl cellosolve:toluene=3:2 (mass ratio), hereafter referred to as solution A-1) was introduced into a flask fitted with a stirrer, reflux condenser, thermometer, dropping funnel, and nitrogen inlet tube, and was heated to 85° C. while stirring and blowing in nitrogen. A solution (hereafter referred to as solution B-1) was also prepared by mixing methacrylic acid, methyl methacrylate, butyl acrylate and styrene in a mass ratio of 25:50:20:5, and 600 parts by mass of solution B-1 was added dropwise over 4 hours to solution A-1 heated to 85° C. After this addition, the temperature was maintained for 2 hours at 85° C. while stirring. In addition, a solution prepared by dissolving 1 part by mass of azobisisobutyronitrile in 100 parts by mass of solution A-1, was added dropwise to the flask over 10 minutes. After the completion of this addition, the temperature was maintained for 5 hours at 85° C. while stirring the solution; this was followed by cooling to obtain the binder polymer. This binder polymer had a nonvolatile fraction of 50 mass % and a weight-average molecular weight of 80,000. The obtained polymer was designated as binder polymer 1.

(Binder Polymer 2)

600 parts by mass of a mixed solution of methyl cellosolve and toluene (methyl cellosolve:toluene=3:2 (mass ratio), hereafter referred to as solution A-2) was introduced into a flask fitted with a stirrer, reflux condenser, thermometer, dropping funnel, and nitrogen inlet tube, and was heated to 85° C. while stirring and blowing in nitrogen. A solution (hereafter referred to as solution B-2) was also prepared by mixing methacrylic acid, methyl methacrylate, 2-ethylhexyl acrylate and styrene in a mass ratio of 25:50:20:5, and 600 parts by mass of solution B-2 was added dropwise over 4 hours to solution A-2 heated to 85° C. After this addition, the temperature was maintained for 2 hours at 85° C. while stirring. In addition, a solution prepared by dissolving 1 parts by mass of azobisisobutyronitrile in 100 parts by mass of solution A-2, was added dropwise to the flask over 10 minutes. After the completion of this addition, the temperature was maintained for 5 hours at 85° C. while stirring the solution; this was followed by cooling to obtain the binder polymer. This binder polymer had a nonvolatile fraction of 50 mass % and a weight-average molecular weight of 80,000. The obtained polymer was designated as binder polymer 2.

(Binder Polymer 3)

600 parts by mass of a mixed solution of methyl cellosolve and toluene (methyl cellosolve:toluene=3:2 (mass ratio), hereafter referred to as solution A-3) was introduced into a flask fitted with a stirrer, reflux condenser, thermometer, dropping funnel, and nitrogen inlet tube, and was heated to 85° C. while stirring and blowing in nitrogen. A solution (hereafter referred to as solution B-3) was also prepared by mixing methacrylic acid, methyl methacrylate and ethyl acrylate in a mass ratio of 20:55:25, and 600 parts by mass of solution B-3 was added dropwise over 4 hours to solution A-3 heated to 85° C. After this addition, the temperature was maintained for 2 hours at 85° C. while stirring. In addition, a solution prepared by dissolving 1 parts by mass of azobisisobutyronitrile in 100 parts by mass of solution A-3, was added dropwise to the flask over 10 minutes. After the completion of this addition, the temperature was maintained for 5 hours at 85° C. while stirring the solution; this was followed by cooling to obtain the binder polymer. This binder polymer had a nonvolatile fraction of 50 mass % and a weight-average molecular weight of 80,000. The obtained polymer was designated as binder polymer 3.

<Preparation of the Photopolymerizable Compounds>

Photopolymerizable compounds 1 to 5 were prepared as follows.

### (Photopolymerizable Compound 1)

2,2-bis(4-(methacryloxypentadecaethoxy)phenyl) (Shin-nakamura Chemical Co., Ltd., product name: “BPE-500”)

(Photopolymerizable compound 2)

polyoxyethylene trimethyldecyl ether monoacrylate (Rhodia Nicca, sample name: “RE-279”, a compound with the above-cited general formula (II) in which R¹ is a hydrogen atom, R² is a C₁₃ alkyl group having 3 tertiary or higher carbon atoms, X is the ethylene group, and n is 5)

### (Photopolymerizable Compound 3)

nonylphenoxypolyethyleneoxy acrylate (Kyoeisha Chemical Co., Ltd., product name: “NP-8EA”)

### (Photopolymerizable Compound 4)

γ-chloro-β-hydroxypropyl-β′-methacryloyloxyethyl-o-phthalate (Hitachi Chemical Co., Ltd., product name: “FA-MECH”)

### (Photopolymerizable Compound 5)

2-ethylhexylcarbitol acrylate (TOAGOSEI Co., Ltd., product name: “Aronix M-120”, a compound with the above-cited general formula (II) in which R¹ is a hydrogen atom, R² is a C₈ alkyl group having 1 tertiary or higher carbon atom, X is the ethylene group, and n is 2)

<Preparation of the Photopolymerization Initiators>

Photopolymerization initiators 1 and 2 were prepared as follows.

### (Photopolymerization Initiator 1)

2-(o-chlorophenyl)-4,5-diphenylimidazole dimer

### (Photopolymerization Initiator 2)

N,N′-tetraethyl-4,4′-diaminobenzophenone

### Examples 1 to 3 and Comparative Examples 1 to 4

Solutions of the photosensitive resin compositions according to Examples 1 to 3 and Comparative Examples 1 to 4 were obtained by mixing the following as shown in Table 1: binder polymer 1 to 3 as component (A), photopolymerizable compound 1 to 5 as component (B), the photopolymerization initiator as component (C), additives, and solvent. The solutions were prepared by first mixing the components other than component (B) and then admixing component (B). The amounts of addition in Table 1 are given in parts by mass. The amount of solids fraction addition is given for component (A).

TABLE 1

| | | Ex. | | | Comp. Ex. 1 | | | |
|---|---|---|---|---|---|---|---|---|
| material | | 1 | 2 | 3 | 1 | 2 | 3 | 4 |
| component | Binder polymer 1 | 50 | — | — | — | — | — | 50 |
| (A) | Binder polymer 2 | — | 50 | — | — | — | — | — |
| | Binder polymer 3 | — | — | 50 | 50 | 50 | 50 | — |
| component | Photopolymerizable | 40 | 35 | 40 | 40 | 40 | 40 | 40 |
| (B) | compound 1 | | | | | | | |
| | Photopolymerizable | 10 | 15 | 10 | — | — | — | — |
| | compound 2 | | | | | | | |
| | Photopolymerizable | — | — | — | 10 | — | — | 10 |
| | compound 3 | | | | | | | |
| | Photopolymerizable | — | — | — | — | 10 | — | — |
| | compound 4 | | | | | | | |
| | Photopolymerizable | — | — | — | — | — | 10 | — |
| | compound 5 | | | | | | | |

| | | |
|---|---|---|
| component | Photopolymerization | 3.5 |
| (C) | initiator 1 | |
| | Photopolymerization | 0.2 |
| | initiator 2 | |
| additive | malachite green | 0.05 |
| | leuco crystal violet | 0.5 |
| solvent | acetone | 15 |
| | toluene | 10 |
| | methanol | 10 |

<Fabrication of the Photosensitive Element>

Photosensitive elements were fabricated according to the following procedure using the photosensitive resin composition solutions according to Examples 1 to 3 and Comparative Examples 1 to 4. The photosensitive resin composition solution was first uniformly coated on polyethylene terephthalate film (width=380 mm, thickness=16 μm, product name: “G2-16”, from Teijin Limited, referred to hereafter as PET film), and the photosensitive layer was then formed by holding for 10 minutes in a forced convection dryer set at 100° C. This was carried out in such a manner that the film thickness of the photosensitive layer after heating was 40 μm. A 22 μm-thick polyethylene film (product name: “NF-13”, from Tamapoly Co., Ltd.) was placed as a protective film on the photosensitive layer thus formed, and the application of pressure with a roll gave the photosensitive element of Examples 1 to 3 and Comparative Examples 1 to 4; this was a photosensitive element in which the photosensitive layer was covered by a protective film.

[Evaluation of the Foaming Property and the Development Sludge and Scum Dispersibility]

The photosensitive layer of the photosensitive element obtained as described above was dissolved, at the rate of 0.25 m² photosensitive layer per 1 L of the aqueous sodium carbonate solution, in a 1000-mL graduated cylinder holding 100 mL of a 1.0 mass % aqueous sodium carbonate solution. Bubbling was then carried out at 30° C. by sending air at 1 L/minute for 3 hours into this solution. The height of the foam from the liquid surface at this time was measured. In addition, the amount of scum (oil) produced on the surface of the solution was visually evaluated based on the evaluation criteria shown in Table 3. The development sludge produced in the solution was then separated using a centrifugal separator, filtered, and thereafter dried for 4 hours at 150° C. and the weight of the development sludge was subsequently measured. The obtained results are shown in Table 2.

[Evaluation of the Adhesive Property]

In order to investigate the adhesive property, the photosensitive element obtained as described above was laminated on a copper-clad laminate. A phototool having a circuit pattern with a line width of 6 to 47 (unit: μm) as a negative for adhesive property evaluation and a phototool having a 21-step tablet were then brought into contact with the photosensitive layer and exposure was carried out using an amount of energy such that the number of remaining steps on the Stauffer 21-step tablet after development was 8.0. The adhesive property was evaluated as the minimum adhering line width after development without stripping. These results are shown in Table 2. A smaller minimum line width value in Table 2 is indicative of a better adhesive property.

[Resolution]

Proceeding as for the evaluation of adhesive property, the photosensitive element was laminated on a copper-clad laminate. A phototool having an circuit pattern with a line width/space width of 30/30 to 200/200 (unit: μm) as a negative for resolution evaluation and a phototool having a 21-step tablet were then brought into contact with the photosensitive layer and exposure was carried out using an amount of energy such that the number of remaining steps on the 21-step tablet after development was 8.0. In this case, the resolution was evaluated as the smallest space width between line widths at which the unexposed region could be cleanly removed by the development treatment. These results are shown in Table 2. Smaller numerical values are better values in this evaluation of resolution.

TABLE 2

| | | | amount of | | |
|---|---|---|---|---|---|
| | foaming | | development | | adhesive |
| | property | scum | sludge | resolution | property |
| | (mm) | dispersibility | (g/L) | (μm) | (μm) |
| Ex. 1 | 15 | 4 | 0.4 | 50 | 30 |
| Ex. 2 | 10 | 4 | 0.4 | 50 | 30 |
| Ex. 3 | 10 | 4 | 0.7 | 50 | 30 |
| Comp. | 60 | 4 | 1.8 | 60 | 35 |
| Ex. 1 | | | | | |
| Comp. | 20 | 1 | 2.1 | 50 | 30 |
| Ex. 2 | | | | | |
| Comp. | 20 | 1 | 1.9 | 50 | 30 |
| Ex. 3 | | | | | |
| Comp. | 100 | 4 | 0.7 | 50 | 30 |
| Ex. 4 | | | | | |

TABLE 3

| level | evaluation criterion |
|---|---|
| 4 | No scum is seen. |
| 3 | A trace amount of scum is seen. |
| 2 | A small amount of scum is seen. |
| 1 | A large amount of scum is seen. |

As is clear from the results shown in Table 2, the photosensitive elements of Examples 1 to 3 were found to give less foaming during development than the photosensitive elements of Comparative Examples 1 to 4 and were found to give a satisfactorily small amount of development sludge production by the developing solution in comparison to the photosensitive elements of Comparative Examples 1 to 4. In addition, it was found that the photosensitive elements of Examples 1 to 3 can provide a thorough inhibition of scum production. Accordingly, the present invention makes it possible to obtain printed circuit boards free of interconnect defects in good yields while at the same time achieving a good reduction in production costs through a reduction in the frequency at which the developing equipment is cleaned and a reduction in the filter change frequency.

### INDUSTRIAL APPLICABILITY

The present invention provides a photosensitive resin composition that gives a satisfactorily low foaming during development and that gives a satisfactory reduction in the amount of development sludge production and in the amount of scum production, as well as a photosensitive element, a method of forming a resist pattern, and a process for producing a printed circuit board employing it.

1. A photosensitive resin composition comprising:
(A) a binder polymer;
(B) a photopolymerizable compound with at least one polymerizable ethylenic unsaturated group in the molecule; and
(C) a photopolymerization initiator,
wherein said photosensitive resin composition comprises, as said component (A), a polymer that contains a compound represented by the following general formula (I) as a polymerization component:
CH₂═C(L¹)-COOL² (I)
(wherein L¹ represents a hydrogen atom or methyl group and L² represents a C₂₋₂₀ alkyl group)
and comprises, as said component (B), a compound represented by the following general formula (II): 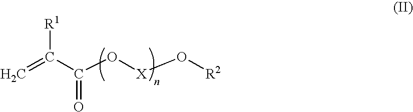
(wherein R¹ represents a hydrogen atom or methyl group, R² represents a C₃₋₂₀ alkyl group that has at least 2 tertiary or higher carbon atoms, X represents a C₂₋₆ alkylene group, and n is an integer from 1 to 20).

2. A photosensitive element comprising a support and a photosensitive layer comprising the photosensitive resin composition according to claim 1 formed on said support.

3. A method of forming a resist pattern comprising:
laminating the photosensitive layer in the photosensitive element according to claim 2 on a circuit formation substrate;
irradiating active light rays onto a prescribed region of the photosensitive layer to induce photocuring of the region exposed to light; and
removing a region other than said region exposed to light.

4. A process for producing a printed circuit board, comprising: etching or plating a circuit formation substrate on which a resist pattern has been formed by the method of forming a resist pattern according to claim 3.
